(19) United States
(12) Patent Application Publication
(10) Pub. No.: US 2026/0156889 A1
(43) Pub. Date: Jun. 4, 2026

(54) METAL-FERROELECTRIC-METAL DEVICE COMPRISING TWO DIMENSIONAL VAN DER WAALS-BONDED TRANSITION METAL CHALCOGENIDE INTERFACIAL LAYER AND METHOD FOR MANUFACTURING THE SAME

(71) Applicants: KOREA INSTITUTE OF MATERIALS SCIENCE, Changwon-si (KR); POSTECH Research and Business Development Foundation, Pohang-si (KR)

(72) Inventors: Yong-hun Kim, Daegu (KR); Hyunsang Hwang, Daegu (KR); Seung-Kwon Hwang, Changwon-si (KR); Kyung Song, Changwon-si (KR); Kyumin Lee, Gwangju (KR); Jung-dae Kwon, Changwon-si (KR); Byeong-Jin Park, Changwon-si (KR); Jong-won Yoon, Changwon-si (KR)

(21) Appl. No.: 19/346,828

(22) Filed: Oct. 1, 2025

(30) Foreign Application Priority Data
Nov. 29, 2024 (KR) 10-2024-0174844

(51) Int. Cl. H10D 62/80; H01L 21/02; H10D 64/68

(52) U.S. Cl. CPC H10D 62/883; H10D 64/689; H10P 14/3236; H10P 14/3436; H10P 14/6339

(57) ABSTRACT

The present disclosure provides a metal-ferroelectric-metal device with a two-dimensional van der Waals-bonded transition metal chalcogenide interfacial layer, and a method for manufacturing the same. More particularly, the present disclosure provides a metal-ferroelectric-metal device with a two-dimensional van der Waals-bonded transition metal chalcogenide interfacial layer to improve crystallinity or domain alignment of the ferroelectric material, and a method for manufacturing the same.

### CROSS-REFERENCE TO RELATED APPLICATIONS

This application claims priority to and benefits of Korean Patent Application No. 10-2024-0174844 under 35 U.S.C § 119, filed on Nov. 29, 2024, in the Korean Intellectual Property Office, the contents of which are incorporated herein in its entirety by reference.

### BACKGROUND

### 1. Technical Field

The present disclosure relates to a metal-ferroelectric-metal device including two-dimensional van der Waals-bonded transition metal chalcogenide interfacial layer and a method for manufacturing the same. More particularly, the present disclosure relates to a metal-ferroelectric-metal device including two-dimensional van der Waals-bonded transition metal chalcogenide interfacial layer for improvement of crystallinity or domain alignment of the ferroelectric material, and a method for manufacturing the same.

### 2. Description of the Related Art

Upon manufacturing a metal-ferroelectric-metal (MFM) device based on a hafnium zirconium oxide (HfₓZr₁₋ₓO₂, HZO, also referred as hafnium-based oxide) that is a ferroelectric material, an ordinary hafnium-based oxide (HZO) may cause an undesired interfacial chemical reaction upon deposition on a lower electrode due to high temperature and oxygen atmosphere by an atomic layer deposition (ALD) process, leading to formation of an oxide material degrading the ferroelectricity. In addition, due to rapid thermal annealing (RTA) for ferroelectric crystallization of the hafnium-based oxide (HZO), oxygen within a hafnium-based oxide (HZO) thin film may diffuse into an electrode, leading to defects, such as formation of numerous oxygen vacancies on an interface. Furthermore, each domain of the hafnium-based oxide (HZO) has a size of tens of nanometers and is randomly oriented in various directions.

Therefore, at a nanoscale level corresponding to an extreme scale, each device exhibits different characteristics, leading to reliability issues. Accordingly, a method and a process are required to resolve the reliability challenges by improving a protection layer for stability of an interface and crystallinity of a hafnium-based oxide (HZO).

As a background of the present disclosure, Korean Patent Publication No. 10-2005-0041089 describes a capacitor of a ferroelectric memory device and a method for manufacturing the same.

### SUMMARY

An object of the present disclosure is to provide a metal-ferroelectric-metal device for improvement of crystallinity or domain alignment of the ferroelectric material.

Another object of the present disclosure is to provide a metal-ferroelectric-metal device with maximized interfacial stability by protecting a lower electrode from formation of an oxide material formed due to an undesired chemical reaction upon deposition of HZO by an ALD process.

Another object of the present disclosure is to provide a metal-ferroelectric-metal device with maximized interfacial stability by controlling oxygen scavenging effect to suppress formation of an oxygen vacancy.

Another object of the present disclosure is to provide a metal-ferroelectric-metal device with simultaneous improvement of high endurance upon repeated operation, and reliability at a nanoscale level of the metal-ferroelectric-metal device.

Another object of the present disclosure is to provide a method for manufacturing a metal-ferroelectric-metal device for simultaneous improvement of high-endurance upon repeated operation, and reliability at a nanoscale level of the metal-ferroelectric-metal device, while also improving processibility and cost-effectiveness of the manufacturing process.

Other objects and advantages of the present disclosure will be more clarified by detailed description, claims, and drawings of the present disclosure.

According to one aspect, a metal-ferroelectric-metal device is provided, the metal-ferroelectric-metal device including a first electrode; an interfacial layer consisting of a two-dimensional transition metal chalcogenide and formed on the first electrode; a ferroelectric layer formed on the interfacial layer; and a second electrode formed on the ferroelectric layer.

According to one embodiment, the interfacial layer may be composed of a plurality of layers, and the plurality of layers may be bonded via van der Waals interactions.

According to one embodiment, the interfacial layer may function as a seed layer for the ferroelectric layer to improve crystallinity or domain alignment of the ferroelectric layer.

According to one embodiment, the transition metal chalcogenide may include one or more species of MoS₂, MoSe₂, MoTe₂, WS₂, WSe₂, WTe₂, ZrS₂, ZrSe₂, HfS₂, HfSe₂, NbSe₂, and ReSe₂.

According to one embodiment, a lattice constant of the transition metal chalcogenide in the interfacial layer may be greater than or equal to 2.5 Å and less than or equal to 3.5 Å.

According to one embodiment, a thickness of the interfacial layer may be greater than or equal to 0.5 nm and less than or equal to 5 nm.

According to one embodiment, the ferroelectric layer may include one or more species of hafnium oxide (HfO₂) and hafnium zirconium oxide (HfZrO).

According to one embodiment, the ferroelectric layer may include a vertically aligned domain.

According to one embodiment, a ferroelectric material of the ferroelectric layer may include o-phase among orthorhombic crystal structures, and a proportion of the o-phase may be greater than or equal to 70%.

According to one embodiment, a variation in polarization of the metal-ferroelectric-metal device may be less than 5% after 10⁴ or more cycles.

According to another aspect, a method for manufacturing a metal-ferroelectric-metal device is provided, the method including: i) forming a first electrode; ii) forming an interfacial layer consisting of a transition metal chalcogenide as a plurality of layers on the first electrode; iii) forming a ferroelectric layer on the interfacial layer; and iv) forming a second electrode on the ferroelectric layer.

According to one embodiment, in the step ii), the plurality of layers of the interfacial layer may be bonded via van der Waals interactions.

According to one embodiment, in the step ii), the interfacial layer may be formed by atomic layer deposition (ALD) or chemical vapor deposition (CVD).

According to one embodiment, in the step iii), the ferroelectric layer may be formed by atomic layer deposition (ALD) or chemical vapor deposition (CVD) at a temperature greater than or equal to 200° C. and less than or equal to 250° C.

According to one embodiment, the method may include crystallizing the ferroelectric layer under nitrogen atmosphere at a temperature greater than or equal to 300° C. and less than or equal to 650° C. after the step iv).

According to one embodiment, a metal-ferroelectric-metal device of the present disclosure may include a two-dimensional van der Waals-bonded transition metal chalcogenide interfacial layer, the interfacial layer functioning as a seed layer of a ferroelectric layer to prove crystallinity or domain alignment of a ferroelectric material.

According to one embodiment, a metal-ferroelectric-metal device of the present disclosure may include a two-dimensional van der Waals-bonded transition metal chalcogenide interfacial layer to improve interfacial stability by protecting against formation of an oxide material degrading ferroelectric characteristics by a chemical reaction occurring on a surface of the first electrode upon HZO deposition via an ALD process.

According to one embodiment, a metal-ferroelectric-metal device of the present disclosure may include a two-dimensional van der Waals-bonded transition metal chalcogenide interfacial layer to improve interfacial stability by controlling oxygen scavenging effect of the interfacial layer to suppress formation of oxygen vacancies.

According to one embodiment, a metal-ferroelectric-metal device of the present disclosure may include a two-dimensional van der Waals-bonded transition metal chalcogenide interfacial layer to simultaneously improve high-endurance upon repeated operation and reliability at a nanoscale level of the metal-ferroelectric-metal device.

According to one embodiment, a method for manufacturing a metal-ferroelectric-metal device may simultaneously improve high-endurance upon repeated operation and reliability at a nanoscale level of the metal-ferroelectric-metal device while improving processibility and cost-effectiveness of the manufacturing process.

### BRIEF DESCRIPTION OF THE DRAWINGS

These and/or other features will become apparent and more readily appreciated from the following description of the embodiments, taken in conjunction with the accompanying drawings in which:

FIG. 1A is a schematic diagram illustrating a device according to one embodiment, in which a WS₂ interfacial layer, a two-dimensional van der Waals-bonded transition metal chalcogenide, is inserted at an interface between a first electrode and HZO;

FIG. 1B is a schematic view simply illustrating FIG. 1A;

FIG. 2 is an illustration showing a manufacturing process of a metal-ferroelectric-metal device including two-dimensional van der Waals-bonded transition metal chalcogenide according to one embodiment of the present disclosure;

FIG. 3 is a graph illustrating ferroelectric behavior in a pristine state depending on presence or absence of a two-dimensional van der Waals-bonded transition metal chalcogenide interfacial layer;

FIG. 4 is a photograph showing color changes depending on a number of WS₂ layers on a sapphire substrate according to one embodiment of the present disclosure;

FIG. 5A is a graph showing intensity of Raman shift depending on a number of WS₂ layers synthesized as a two-dimensional van der Waals-bonded transition metal chalcogenide interfacial layer;

FIG. 5B is a graph showing Raman shift difference depending on a number of synthesized WS₂ layers;

FIG. 6A is a graph showing variation in polarization depending on a voltage according to a number of WS₂ layers on a first electrode of TiN;

FIG. 6B is a graph showing variation in polarization depending on a voltage for a third through fifth layers of WS₂ on a first electrode of TiN;

FIG. 7A is a graph showing variation in polarization depending on a voltage according to a number of WS₂ layers on a first electrode of W;

FIG. 7B is a graph showing variation in polarization depending on a voltage for a third through fifth layers of WS₂ on a first electrode of W;

FIG. 8A is a graph showing a proportion of o-phase (111) representing ferroelectricity in a thin film of HZO according to presence or absence of a two-dimensional van der Waals-bonded transition metal chalcogenide interfacial layer;

FIG. 8B is a graph showing a relative proportion of o-phase representing ferroelectricity in a thin film of HZO according to presence or absence of a two-dimensional van der Waals-bonded transition metal chalcogenide interfacial layer;

FIG. 9A is a graph illustrating a bonding energy intensity at a bottom interface of HZO depending on presence or absence of a two-dimensional van der Waals-bonded transition metal chalcogenide interfacial layer;

FIG. 9B is a graph showing a defect proportion at a bottom interface of HZO depending on presence or absence of a two-dimensional van der Waals-bonded transition metal chalcogenide interfacial layer;

FIG. 10A is a graph showing a variation in polarization of an MFM device without a two-dimensional van der Waals-bonded transition metal chalcogenide interfacial layer, comparing a pristine state with a state after more than equal to 10⁴ operation cycles;

FIG. 10B is a graph showing a variation in polarization of an MFM device with a two-dimensional van der Waals-bonded transition metal chalcogenide interfacial layer, comparing a pristine state with a state after more than equal to 10⁴ operation cycles;

FIG. 11 is a transmission electron microscopy (TEM) image showing different crystallinities and domain alignments of HZO depending on presence or absence of a two-dimensional van der Waals-bonded transition metal chalcogenide interfacial layer;

FIG. 12 is a photograph showing comparison of interplanar distances between underlying WS₂, a two-dimensional van der Waals-bonded transition metal chalcogenide interfacial layer, and o-phase (111) of HZO;

FIG. 13 Is a Tem Image Showing Crystallinity of Hzo on an Interfacial Layer of Nb₂O₅, a transition metal oxide;

FIG. 14 is a TEM image showing crystallinity of HZO on an interfacial layer of NbSe₂, a two-dimensional van der Waals-bonded transition metal chalcogenide;

FIG. 15A is an illustration showing distribution of each domain of HZO depending on absence of an interfacial layer of WS₂, a two-dimensional van der Waals-bonded transition metal chalcogenide;

FIG. 15B is an illustration showing distribution of each domain of HZO depending on presence of an interfacial layer of WS₂, a two-dimensional van der Waals-bonded transition metal chalcogenide;

FIG. 16A is a graph showing variation in polarization of an MFM device without an interfacial layer of WS₂, a two-dimensional van der Waals-bonded transition metal chalcogenide, measured from 1 V to 3.5 V in 0.1 V increments;

FIG. 16B is a graph showing variation in polarization of a MFM device with an interfacial layer of WS₂, a two-dimensional transition metal chalcogenide, measured from 1 V to 3.5 V in 0.1 V increments;

FIG. 17A is an illustration showing a variation in polarization depending on a number of repeated operation cycle of an MFM device without an interfacial layer of WS₂, a two-dimensional van der Waals-bonded transition metal chalcogenide;

FIG. 17B an illustration showing a variation in polarization depending on a number of repeated operation cycle of an MFM device with an interfacial layer of WS₂, a two-dimensional transition metal chalcogenide; and

FIG. 18 is a graph showing comparison of ferroelectricity property variations at a nanoscale level depending on presence or absence of an interfacial layer of WS₂, a two-dimensional van der Waals-bonded transition metal chalcogenide.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Objects, specific advantages and novel features of the present disclosure will become more apparent from the following detailed description and embodiments with references to the accompanying drawings.

It should be understood that the terms and expressions used in the present specification and claims should not be interpreted in a conventional or dictionary meanings. Rather, they shall be construed in accordance with the technical idea of the present disclosure based on the principle that the inventor is entitled to define the terms appropriately in order to best describe the invention.

As described herein, when an element, such as a layer, a portion, or a substrate, is described as being “on,” “connected to,” or “coupled to” another element, it may be directly “on,” “connected to,” or “coupled to” the other element, or have yet one or more elements therebetween. However, when an element is “directly on,” “directly connected to,” or “directly coupled to” another element, there are no elements therebetween.

A terminology described herein is merely for the purpose of describe a particular embodiment and is not intended to be limiting the present disclosure. As used herein, a singular expression also includes a plural form unless the context clearly indicates otherwise.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

As described herein, when a part is described to “include” an element, unless explicitly stated otherwise, it is understood that the part may include additional elements and is not limited to excluding other elements. Furthermore, as described herein, the term “on” refers to being located either above or below the subject part, and does not necessarily mean being positioned on the upper side with respect to the gravitational direction.

The present disclosure may have various modifications and numerous embodiments, and specific embodiments are illustrated in the accompanying drawings and escribed in detail herein. However, this is not intended to limit the present disclosure to particular embodiments, but rather, it is to be understood that all modifications, equivalents, and substitutions falling within the idea and scope of the present disclosure are included. In the present disclosure, detailed descriptions about known technologies may be omitted when such descriptions may obscure the gist of the present disclosure.

Hereinafter, embodiments of the present disclosure will be described in detail with references to the accompanying drawings. Upon descriptions with references to the accompanying drawings, same or corresponding elements are denoted by same reference numerals, and redundant descriptions thereof will be omitted.

As described herein, a term “domain” refers to each region of a material of a single fragment.

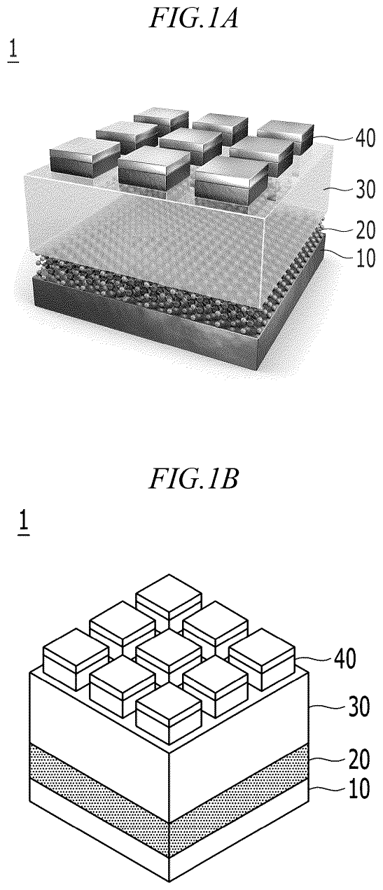

FIG. 1A is a schematic diagram illustrating a device according to one embodiment, in which a WS₂ interfacial layer, a two-dimensional van der Waals-bonded transition metal chalcogenide, is inserted at an interface between a first electrode and HZO, and FIG. 1B is a schematic view simply illustrating FIG. 1A.

Referring to FIG. 1A and FIG. 1B, the metal-ferroelectric-metal device 1 according to one aspect of the present disclosure includes a first electrode 10, an interfacial layer 20 consisting of a two-dimensional transition metal chalcogenide and formed on the first electrode 10; a ferroelectric layer 30 formed on the interfacial layer 20; and a second electrode 40 formed on the ferroelectric layer 30.

Materials of the first electrode 10 and the second electrode 40 may each independently include TiN, TaN, Ti, Ta, TiCN, TiSiN, WSiN, TiAlN, TaAlN, TiAlCN, TiW, RuTiN, RuCN, Pt, Au, or Al. The first electrode 10 and the second electrode 20 may be formed of a same material or of different materials. For example, both the first electrode 10 and the second electrode 20 may be formed of TiN.

A two-dimensional transition metal chalcogenide is a two-dimensional material, and the two-dimensional material is a solid composed of a single-layer or half-layer of atoms arranged in a pre-determined crystal structure. The two-dimensional material may have a layered structure. In an electronic structure aspect, a two-dimensional material may be defined as a material whose density of state (DOS) follows quantum well behavior. Since the density of state (DOS) follows quantum well behavior in materials laminated with a plurality of two-dimensional unit material layers (monolayers), in such perspective, a structure in which the monolayer is repeatedly laminated may also be referred as “a two-dimensional material.”

Although the present disclosure is not limited thereto, the interfacial layer 20 may be composed of a plurality of (i.e. two or more) layers, and the plurality of layers may be bonded by van der Waals interactions. According to the above configuration, the fist electrode 10 may be protected, and oxygen scavenging effect of the interfacial layer 20 may be controlled to suppress formation of oxygen vacancies. Accordingly, interfacial stability may be improved.

Although the present disclosure is not limited thereto, the interfacial layer 20 may function as a seed layer of the ferroelectric layer 30 to improve crystallinity or domain alignment of the ferroelectric layer 30. According to the described configuration, high-endurance and reliability at a nanoscale level upon repeated operation cycles of the metal-ferroelectric-metal device 1 may be simultaneously improved.

Although the present disclosure is not limited thereto, the transition metal chalcogenide may include one or more species of MoS₂, MoSe₂, MoTe₂, WS₂, WSe₂, WTe₂, ZrS₂, ZrSe₂, HfS₂, HfSe₂, NbSe₂, and ReSe₂. Because including WS₂ or NbSe₂ improves very stable ferroelectricity characteristics without wake-up effects or significant fatigue and also improves crystallinity or domain alignment of the ferroelectric layer 30 of the metal-ferroelectric-metal device 1, including WS₂ or NbSe₂ may be more suitable.

Although present disclosure is not limited thereto, in the interfacial layer 20, a lattice constant of the transition-metal chalcogenide may be greater than or equal to 2.5 Å and less than or equal to 3.5 Å, greater than or equal to 3.0 Å and less than or equal to 3.5 Å, or greater than or equal to 3.1 Å and less than or equal to 3.3 Å. In case that a lattice constant of the transition-metal chalcogenide in the interfacial layer 20 is less than 2.5 Å or greater than 3.5 Å, lattice mismatching may increase, and the interfacial layer 20 may be difficult to be used as a seed layer. Accordingly, crystallinity of the ferroelectric layer 30 may be degraded.

Although the present disclosure is not limited thereto, a thickness of the interfacial layer 20 may be greater than or equal to 0.5 nm and less than or equal to 5 nm. In case that a thickness of the interfacial layer 20 is less than 0.5 nm, processibility of the metal-ferroelectric-metal device 1 may be degraded, and in case that a thickness of the interfacial layer 20 is greater than 5 nm, high-endurance and reliability at a nanoscale level upon repeated operation cycles of the metal-ferroelectric-metal device 1 may be degraded.

Although the present disclosure is not limited thereto, the ferroelectric layer 30 may include one or more species of hafnium oxide (HfO₂) and hafnium zirconium oxide (HfZrO). The ferroelectric layer 30 may be composed of hafnium zirconium oxide (HfZrO), which can significantly increase the o-phase of the orthorhombic structure in the thin film, thereby enhancing the ferroelectric characteristics.

Although the present disclosure is not limited thereto, the ferroelectric layer 30 may include a vertically aligned domain. According to the configuration, high-endurance and reliability at a nanoscale level upon repeated operation cycles of the metal-ferroelectric-metal device 1 may be simultaneously improved. Although the present disclosure is not limited thereto, a ferroelectric material of the ferroelectric layer 30 may include o-phase among orthorhombic crystal structures, and a proportion of the o-phase may be greater than or equal to 70%. Accordingly, ferroelectricity characteristics may be improved.

According to one embodiment, a variation in polarization of the metal-ferroelectric-metal device may be less than 5% after 10⁴ or more cycles.

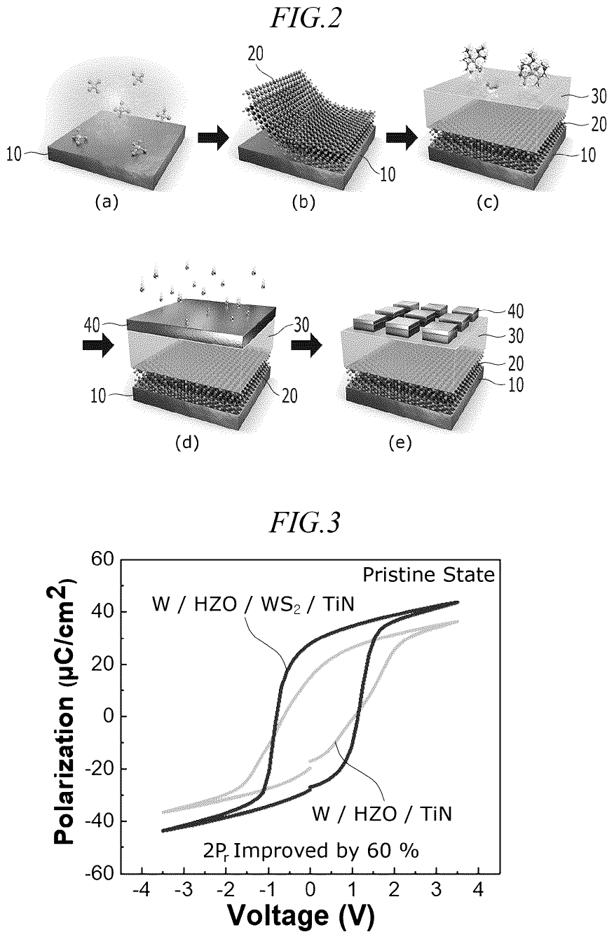

FIG. 2 is an illustration showing a manufacturing process of a metal-ferroelectric-metal device including two-dimensional van der Waals-bonded transition metal chalcogenide according to one embodiment of the present disclosure.

Referring to FIG. 2, a method for manufacturing a metal-ferroelectric-metal device 1 according to another aspect of the present disclosure includes: i) forming a first electrode 10; ii) forming a plurality of layers (i.e. two or more) of interfacial layers 20 consisting of a transition metal chalcogenide on the first electrode 10; iii) forming a ferroelectric layer 30 on the interfacial layer 20; and iv) forming a second electrode 40 on the ferroelectric layer 30.

In the step i), a first electrode 10 is formed (see (a) of FIG. 2). The first electrode 10 may be formed on a substrate by a method, such as plating, sputtering, vapor deposition. Although the present disclosure is not limited thereto, TiN, TaN, Ti, Ta, TiCN, TiSiN, WSiN, TiAlN, TaAlN, TiAlCN, TiW, RuTiN, RuCN, Pt, Au, or Al may be used as a material of the first electrode 10.

In the step ii), an interfacial layer 20 consisting of a transition metal chalcogenide is formed on the first electrode 10 as a plurality of (i.e. two or more) layers (see (b) of FIG. 2). The interfacial layer 20 may be formed as a plurality of (i.e. two or more) layers by heating and transferring the transition metal chalcogenide on the first electrode 10. Although it is not limited thereto, forming the interfacial layer 20 consisting of a transition metal chalcogenide as a plurality of (i.e. two or more) layers on the first electrode 10 may be achieved by dry transfer or wet transfer.

Although the present disclosure is not limited thereto, the transition metal chalcogenide may include one or more species of MoS₂, MoSe₂, MoTe₂, WS₂, WSe₂, WTe₂, ZrS₂, ZrSe₂, HfS₂, HfSe₂, NbSe₂, and ReSe₂. Because including WS₂ or NbSe₂ improves very stable ferroelectricity characteristics without wake-up effects or significant fatigue and also improves crystallinity or domain alignment of the ferroelectric layer 30 of the metal-ferroelectric-metal device 1, including WS₂ or NbSe₂ may be more suitable.

According to (c) of FIG. 2, in the step iii), a ferroelectric layer 30 is formed on the interfacial layer 20. The ferroelectric layer 30 on the interfacial layer 20 may be formed by atomic layer deposition (ALD) or chemical vapor deposition (CVD). The ferroelectric layer 20 may include one or more species of hafnium oxide (HfO₂) and hafnium zirconium oxide (HfZrO). Using hafnium zirconium oxide (HfZrO) as the ferroelectric layer 30 may significantly increase the o-phase of the orthorhombic structure in the thin film, thereby improving ferroelectric characteristics.

According to (d) and (e) of FIG. 2, in the step iv), a second electrode 40 is formed on the ferroelectric layer 30. The second electrode 40 may be formed on the ferroelectric layer 30 using a same method as for the first electrode 10. The second electrode 40 may be formed with a material same as or different from a material of the first electrode 10.

According to one embodiment, in the step ii), the plurality of interfacial layers 20 may be bonded via van der Waals interactions.

According to one embodiment, the step iii) may include forming a ferroelectric layer 30 by atomic layer deposition (ALC) or chemical vapor deposition (CVD). Although the present disclosure is not limited thereto, forming the ferroelectric layer 30 by atomic layer deposition (ALD) may improve interfacial stability by protecting against oxide formation that degrades ferroelectricity characteristics due to a chemical reaction occurring on a surface of the first electrode 10.

According to one embodiment, in the step iii), the ferroelectric layer 30 may be formed by atomic layer deposition (ALD) or chemical vapor deposition (CVD) at a temperature greater than or equal to 200° C. and less than or equal to 250° C. Although the present disclosure is not limited thereto, a temperature for formation of the ferroelectric layer 30 may suitably be in the range of 200° C. to 250° C. for excellent interfacial stability. In case that a temperature for formation of the ferroelectric layer 30 is less than 200° C., a precursor may not be sufficiently activated, and reactivity with the interfacial layer 20 may be degraded. Accordingly, formation of the interfacial layer 20 may not be sufficiently achieved. Since a precursor may go through thermal decomposition in case that a temperature is greater than 250° C., it may be unsuitable.

According to one embodiment, a step of crystalizing the ferroelectric layer 30 under nitrogen atmosphere at a temperature greater than 300° C. and less than 650° C. may be included after the step iv). Although the present disclosure is not limited thereto, a temperature for crystallization of the ferroelectric layer 30 may suitably be in the range of 300° C. to 650° C. for formation of the ferroelectric layer 30 with more excellent film quality. In case that a temperature for crystallization of the ferroelectric layer 30 is less than 300° C., the ferroelectric layer 30 may not be sufficiently crystalized. In case that the temperature is greater than 650° C., interfacial stability with the interfacial layer 20 may be degraded, and uniformity of the ferroelectric layer 30 may be degraded. Although the present disclosure is not limited thereto, the ferroelectric layer 30 may be crystalized under nitrogen atmosphere at a temperature greater than or equal to 300° C. and less than or equal to 650° C. for 20 to 40 seconds.

Hereinafter, the present disclosure is described in detail with references to embodiments.

### Embodiment 1. Manufacture of a Metal-Ferroelectric-Metal Device Including an Interfacial Layer of a Two-Dimensional Van Der Waals-Bonded Transition Metal Chalcogenide

FIG. 2 is an illustration showing a manufacturing process of a metal-ferroelectric-metal device using two-dimensional van der Waals-bonded transition metal chalcogenide according to one embodiment of the present disclosure. Referring to FIG. 2, a method for manufacturing a metal-ferroelectric-metal device may include i) forming a first electrode; ii) forming an interfacial layer consisting of a transition metal chalcogenide on the first electrode as a plurality of (i.e. two or more) layers; iii) forming a ferroelectric layer on the interfacial layer; and iv) forming a second electrode on the ferroelectric layer.

A first electrode (such as TiN and W) was deposited on a substrate of sapphire or SiO₂. An interfacial layer was formed to a thickness greater than or equal to 0.5 nm and smaller than or equal to 5 nm as a plurality of (i.e. two or more) layers by transferring WS₂, a transition metal chalcogenide, on the first electrode.

In the present disclosure, a ferroelectric layer was formed on the interfacial layer at 250° C. by atomic layer deposition (ALD) of HZO with an ALD reactor (Lucida D100 ALD, NCD) using precursor composition of TEMA-Hf (Tetrakis(ethylmethylamino)hafnium) and TEMA-Zr (Tetrakis(ethylmethylamino)zirconium) and ozone. As an oxidizing agent, ozone of 276 g/m³ generated using an ozone generator (AX8560, MKS) was used. Nitrogen gas (ultra-high purity, 99.995% purity) as carrier gas was supplied at a flow rate of 100 sccm. A purging step was applied after the step of exposure to precursor and ozone.

A second electrode was formed on the ferroelectric layer.

Thereafter, the ferroelectric layer was crystalized under nitrogen atmosphere at 600° C. for 30 seconds using a rapid thermal process (RTP) equipment (Real RTP-100, ULTECH).

FIG. 1A is a schematic diagram illustrating a device according to one embodiment, in which a WS₂ interfacial layer, a two-dimensional van der Waals-bonded transition metal chalcogenide, is inserted at an interface between a first electrode and HZO. According to FIG. 1A, a structure represents a completed metal-two dimensional van der Waals-bonded transition metal chalcogenide interfacial layer-ferroelectric-metal device manufactured by a method for manufacturing a metal-ferroelectric-metal device using the two dimensional van der Waals-bonded transition metal chalcogenide shown in FIG. 2.

### Experimental Example 1. Evaluation of Ferroelectricity of a Deposited Hzo Thin Film

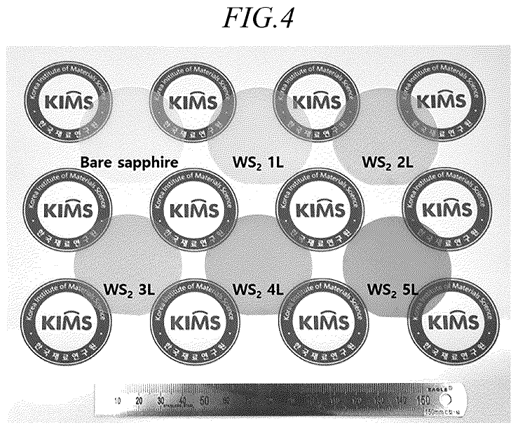

Polarization-voltage (P-V) curves were analyzed to examine ferroelectricity of a deposited HZO thin film depending on presence or absence of a transition metal chalcogenide interfacial layer. FIG. 3 is a graph illustrating ferroelectric behavior in a pristine state depending on presence or absence of a two-dimensional van der Waals-bonded transition metal chalcogenide interfacial layer.

According to FIG. 3, the conventional HZO MFM device did not exhibit its 100% performance in a pristine state due to interfacial defects. However, the device having a two-dimensional WS₂ exhibited increase of 60% or more in remanent polarization (Pᵣ) at 0 V in the pristine state.

### Experimental Example 2. Evaluation of Ferroelectric Behavior Depending on a Number of Layers of WS₂

Raman spectroscopy and polarization-voltage (P-V) curve were analyzed to examine ferroelectric behavior depending on a number of WS₂ layers deposited as a transition metal chalcogenide interfacial layers.

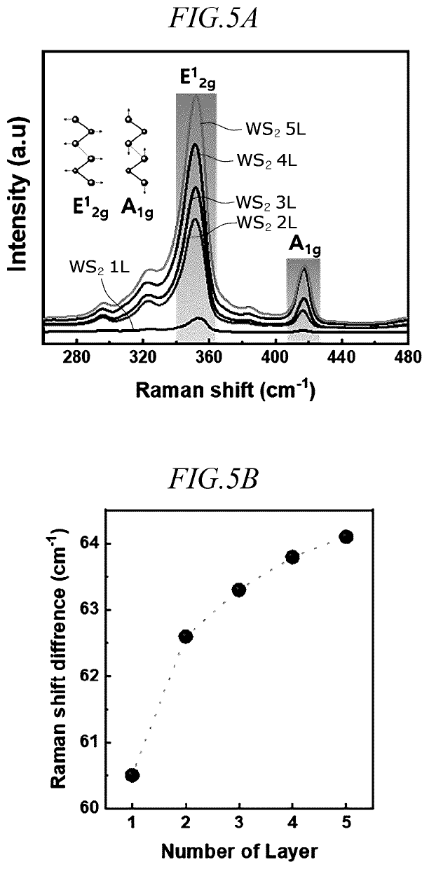

FIG. 4 is a photograph showing color changes depending on a number of WS₂ layers on a sapphire substrate according to one embodiment of the present disclosure. Each substrate has a size of 2 inches, and it was observed that the color became darker as the number of layers increased.

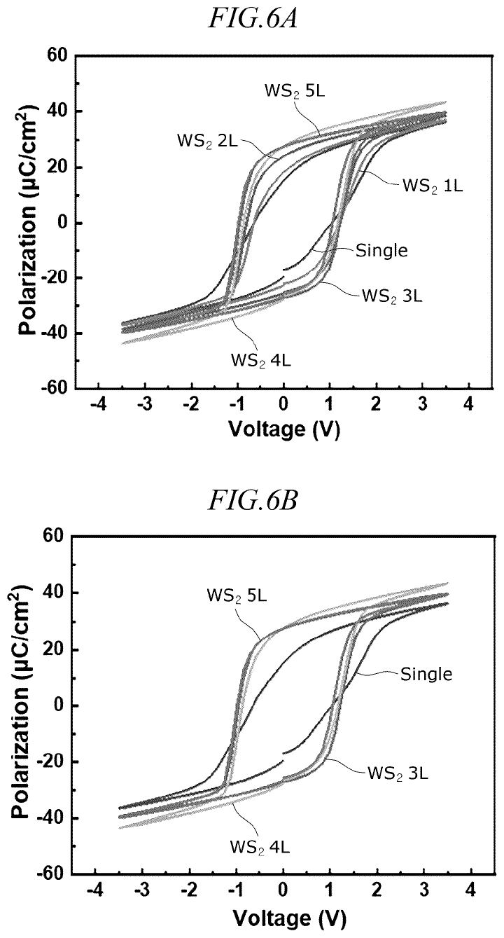

FIG. 5A is a graph showing intensity of Raman shift depending on a number of WS₂ layers synthesized as a two-dimensional van der Waals-bonded transition metal chalcogenide interfacial layer, and FIG. 5B is a graph showing Raman shift difference depending on a number of synthesized WS₂ layers. According to FIG. 5A, main peaks of WS₂ correspond to E¹_{2g} corresponding to a vibration mode of W and S atoms in a horizontal direction and A_{1g} corresponding to a vibration mode of an S atom in a vertical direction. As a number of layers increases, intensity of each peak increases. According to FIG. 5B, as a number of layers increases, a difference between two peaks increases.

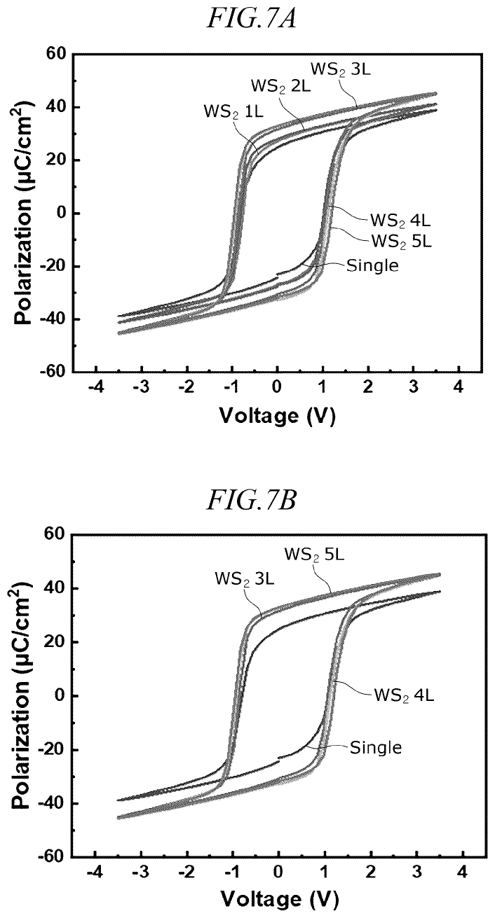

FIG. 6A is a graph showing variation in polarization depending on a voltage according to a number of WS₂ layers on a first electrode of TiN, and FIG. 6B is a graph showing variation in polarization depending on a voltage for a third through fifth layers of WS₂ on a first electrode of TiN. FIG. 6A shows that ferroelectricity behavior characteristics are improved as WS₂ is positioned on an interface between TiN, which is the first electrode, and HZO. FIG. 6B indicates that WS₂ exhibits excellent ferroelectricity behavior characteristics when there are 3 or more layers of WS₂.

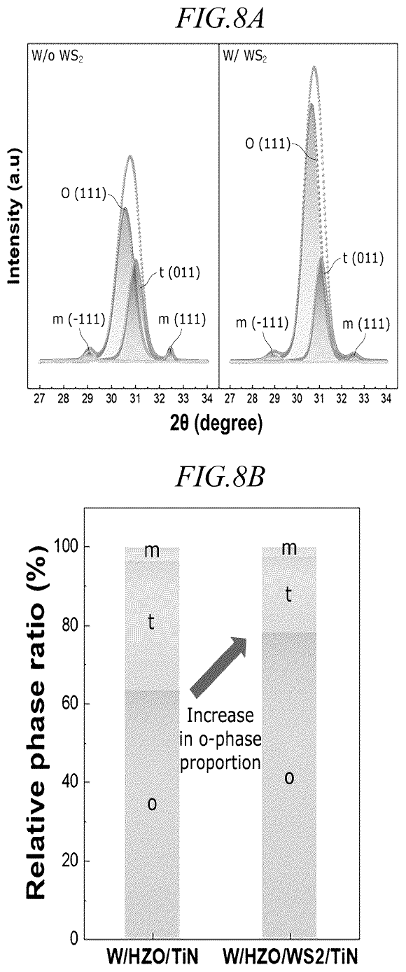

FIG. 7A is a graph showing variation in polarization depending on a voltage according to a number of WS₂ layers on a first electrode of W, and FIG. 7B is a graph showing variation in polarization depending on a voltage for a third through fifth layers of WS₂ on a first electrode of W. FIG. 7A shows that ferroelectricity behavior characteristics are improved as WS₂ is positioned on an interface between W, which is the first electrode, and HZO. FIG. 7B indicates that WS₂ exhibits excellent ferroelectricity behavior characteristics when there are 3 or more layers of WS₂. Accordingly, even in case that the first electrode is TiN or W, excellent ferroelectricity behavior characteristics are shown when there are 3 or more layers of WS₂.

### Experimental Example 3. Evaluation of Properties of an MFM Device and a HZO Layer

A crystalline structure of the HZO layer is measured using Grazing Incidence X-ray Diffraction (GIXRD) (Empyrean, Panalytical).

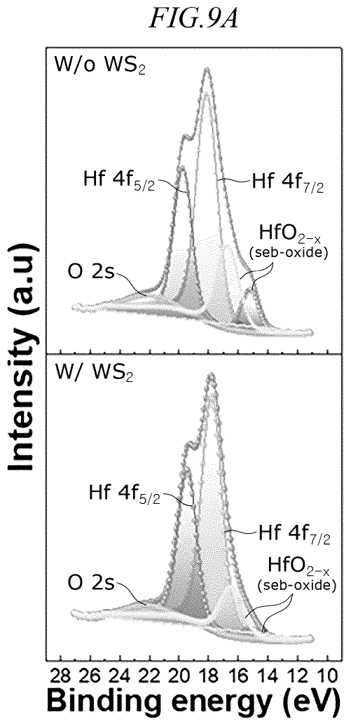

FIG. 8A is a graph showing a proportion of o-phase (111) representing ferroelectricity in a thin film of HZO according to presence or absence of a two-dimensional van der Waals-bonded transition metal chalcogenide interfacial layer, and FIG. 8B is a graph showing a relative proportion of o-phase representing ferroelectricity in a thin film of HZO according to presence or absence of a two-dimensional van der Waals-bonded transition metal chalcogenide interfacial layer. FIG. 8A shows that o-phase of the orthorhombic structure in the HZO thin film is dramatically increased when the two-dimensional van der Waals-bonded transition metal chalcogenide is included in the interfacial layer. FIG. 8B shows that a proportion of o-phase of the orthorhombic structure is 70% or more when the two-dimensional van der Waals-bonded transition metal chalcogenide is included in the interfacial layer, showing a significant increase compared to when the two-dimensional van der Waals-bonded transition metal chalcogenide is not included.

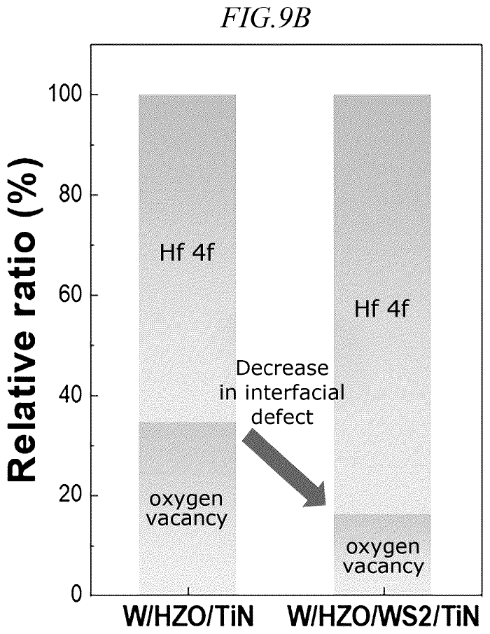

FIG. 9A is a graph illustrating a bonding energy intensity at a bottom interface of HZO depending on presence or absence of a two-dimensional van der Waals-bonded transition metal chalcogenide interfacial layer, and FIG. 9B is a graph showing a defect proportion at a bottom interface of an HZO interfacial layer depending on presence or absence of a two-dimensional transition metal chalcogenide. FIG. 9A and FIG. 9B show a decrease in oxygen vacancy of the lower interface of the HZO by controlling oxygen scavenging effects in which oxygen at the interface between the lower electrode and the HZO migrates through the two-dimensional van der Waals-bonded transition chalcogenide.

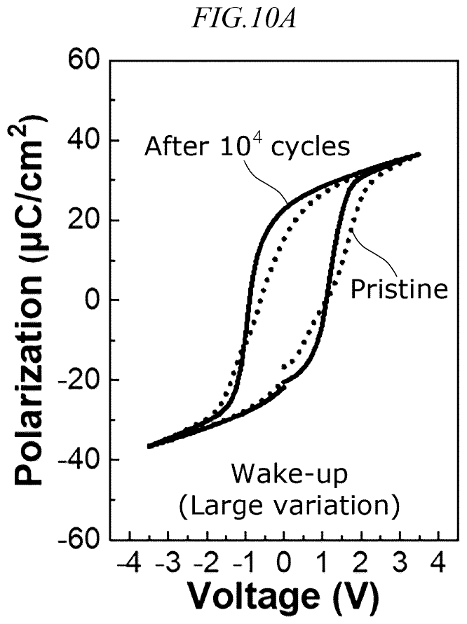

FIG. 10A is a graph showing a variation in polarization of an MFM device without a two-dimensional van der Waals-bonded transition metal chalcogenide interfacial layer, comparing a pristine state with a state after more than equal to 10⁴ operation cycles, and FIG. 10B is a graph showing a variation in polarization of an MFM device with a two-dimensional van der Waals-bonded transition metal chalcogenide, comparing a pristine state with a state after more than equal to 10⁴ operation cycles. A large number of oxygen vacancies of the HZO thin film are generated at the interface between the first electrode and the HZO thin film, which significantly affects the initial ferroelectricity characteristics as well as characteristics after repeated operations. This phenomenon is known as the wake-up effect. In a conventional hafnium oxide-based ferroelectric material, a remanent polarization either increases or decreases due to the wake-up effect and fatigue upon a number of repeated operations increases. FIG. 10A shows that the wake-up effects are caused in an MFM device without the two-dimensional van der Waals-bonded transition metal chalcogenide. FIG. 10B shows that the MFM device with the two-dimensional van der Waals-bonded transition metal chalcogenide has very stable ferroelectricity characteristics without wake-up effects and severe fatigue as there are nearly no changes in polarization after 10⁴ or more operations by controlling interfacial defects.

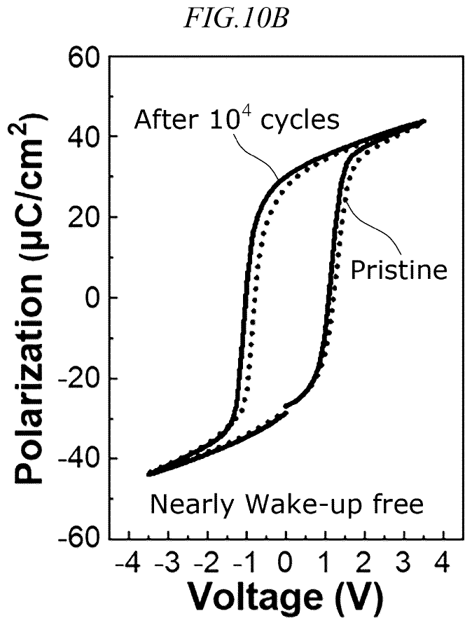

FIG. 11 is a transmission electron microscopy (TEM) image showing different crystallinities and domain alignments of HZO depending on presence or absence of a two-dimensional van der Waals-bonded transition metal chalcogenide interfacial layer. According to FIG. 11, the crystallinity of the ALD-based HZO is disordered, and also orientations between domains are misaligned. Therefore, the structure is typically not clearly visible in TEM images. However, it is observed that, in case that WS₂, a two-dimensional van der Waals-bonded transition metal chalcogenide, is inserted, the HZO domains are well aligned vertically in addition to excellent crystallinity of the HZO.

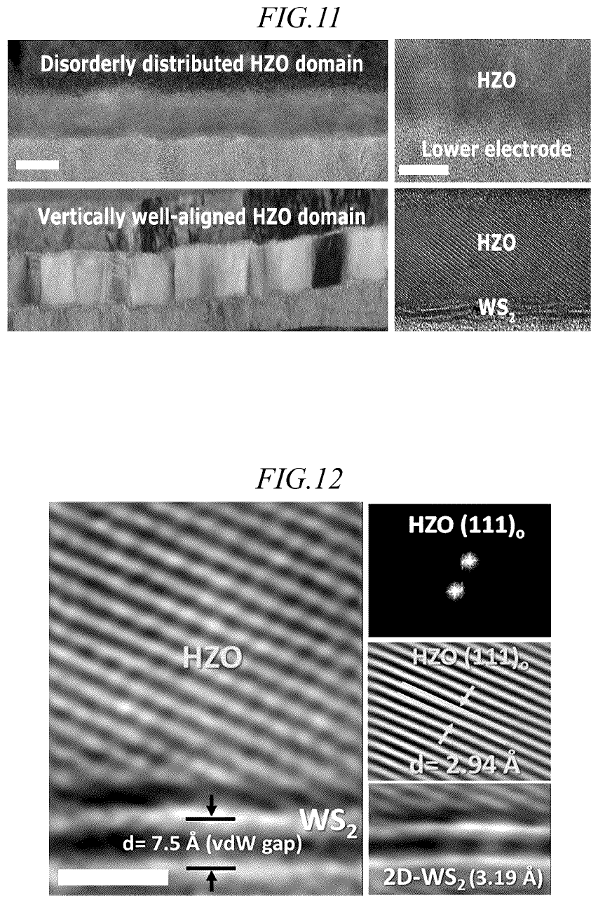

FIG. 12 is a photograph showing comparison of interplanar distances between underlying WS₂, a two-dimensional van der Waals-bonded transition metal chalcogenide interfacial layer, and o-phase (111) of HZO. An interplanar distance of the o-phase (111) in the HZO is approximately 2.94 Å, and a lattice constant of WS₂ is 3.19 Å. In comparison the above, a proportion of the lattice mismatching is approximately 7.8%, indicating possibility of use as an excellent seed layer and possibility of obtaining excellent crystallinity of HZO. Similar effects can be anticipated not only with WS₂ but also other two-dimensional van der Waals-bonded transition metal chalcogenide having a similar lattice structure, such as MoS₂, MoSe₂, MoTe₂, WSe₂, WTe₂, NbS₂, and NbSe₂.

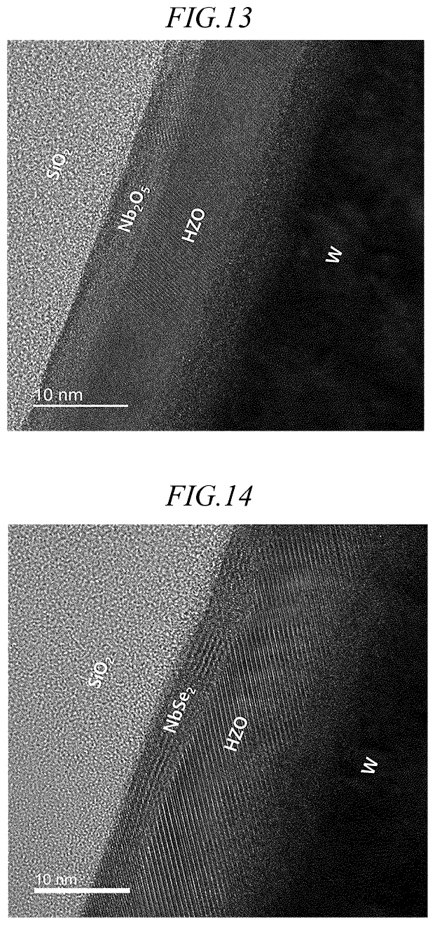

FIG. 13 is a TEM image showing crystallinity of HZO on an interfacial layer of Nb₂O₅, a transition metal oxide. FIG. 13 shows the disordered alignment of crystallinity of HZO.

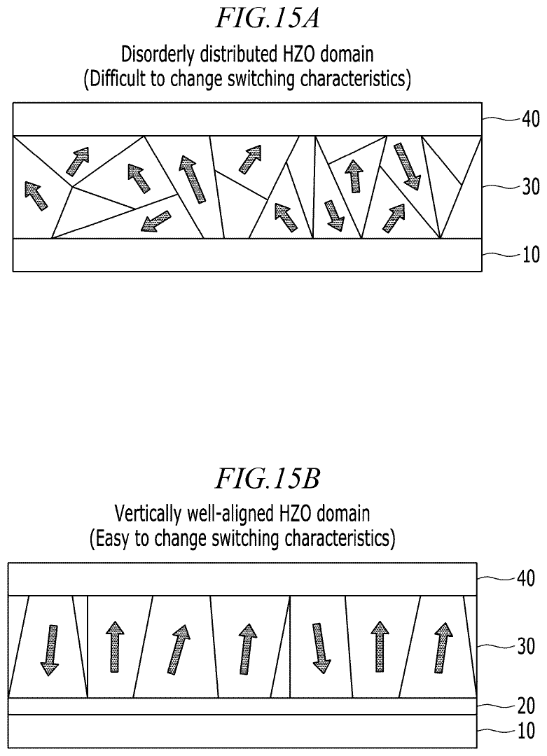

FIG. 14 is a TEM image showing crystallinity of HZO on an interfacial layer of NbSe₂, a two-dimensional van der Waals-bonded transition metal chalcogenide. Referring to FIG. 14, excellent crystallinity of the HZO shown with WS₂ may be obtained with other two-dimensional transition metal chalcogenide, such as NbSe₂.

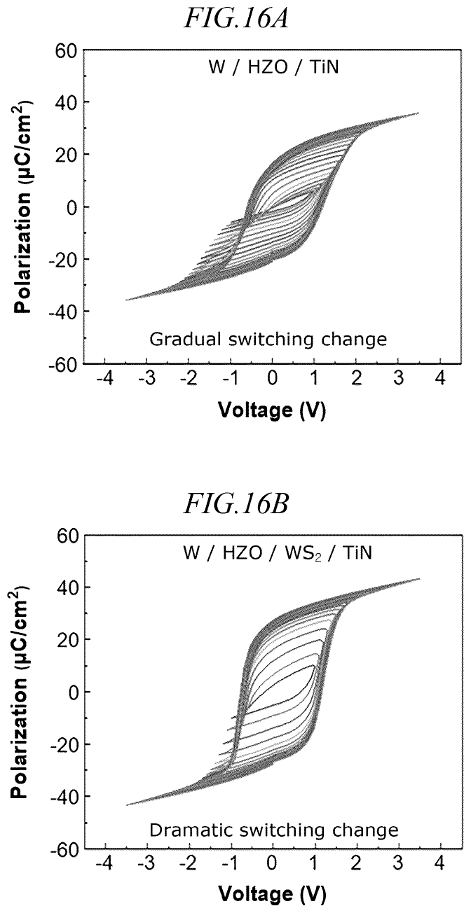

FIG. 15A and FIG. 15B are an illustration showing distribution of each domain of HZO depending on presence or absence of an interfacial layer of WS₂, a two-dimensional van der Waals-bonded transition metal chalcogenide. Referring to FIG. 15A, domains in a conventional HZO has disordered distribution and crystal sizes and exhibit different shapes. Accordingly, switching characteristics are affected by a voltage applied to each domain, and it is difficult to achieve changes in characteristics. FIG. 15B shows vertically well-aligned HZO domain with interfacial stability due to effects of two-dimensional WS₂ positioned at an interface between the lower electrode and the HZO. Switching characteristics of these domains exhibit may be easily changed due to the excellent crystallinity and alignment orientation.

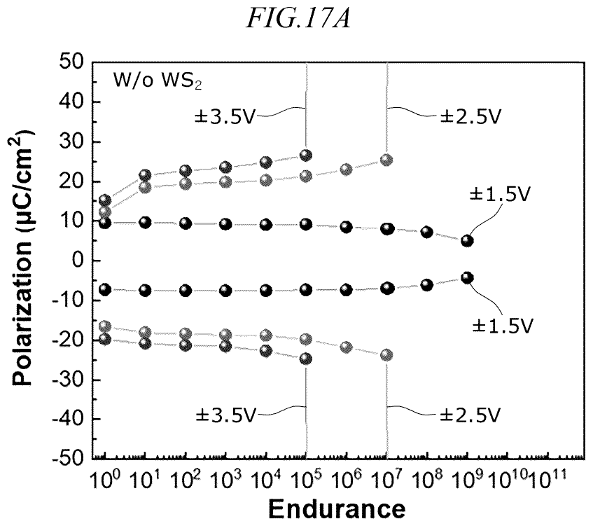

FIG. 16A is a graph showing variation in polarization of an MFM device without an interfacial layer of WS₂, a two-dimensional van der Waals-bonded transition metal chalcogenide, measured from 1 V to 3.5 V in 0.1 V increments, and FIG. 16B is a graph showing variation in polarization of a MFM device with an interfacial layer of WS₂, a van der Waals-bonded two-dimensional transition metal chalcogenide, measured from 1 V to 3.5 V in 0.1 V increments. FIG. 16A shows that ferroelectricity in the conventional HZO gradually changes as a voltage increases. FIG. 16B shows that ferroelectricity dramatically changes as a voltage increases due to interfacial stability and excellent crystallinity and alignment orientation by WS₂ inserted to the interface between the lower electrode and HZO.

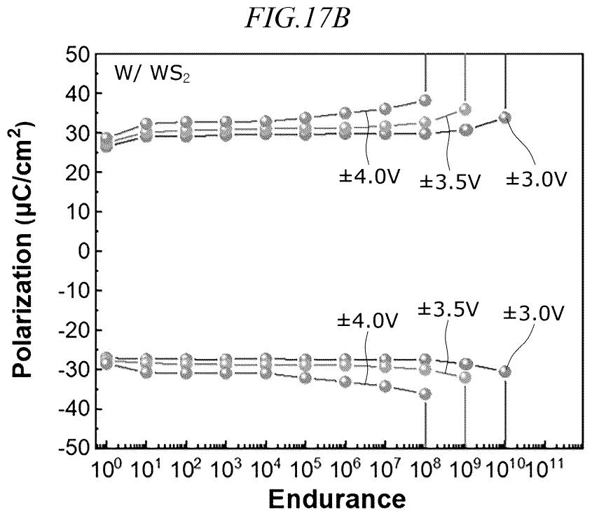

FIG. 17A is an illustration showing a variation in polarization depending on a number of repeated operation cycle of an MFM device without an interfacial layer of WS₂, a two-dimensional van der Waals-bonded transition metal chalcogenide, and FIG. 17B an illustration showing a variation in polarization depending on a number of repeated operation cycle of an MFM device with WS₂, a two-dimensional transition metal chalcogenide. An MFM device with an interfacial layer of WS₂, a two-dimensional van der Waals-bonded transition metal chalcogenide, according to the present disclosure has more improved endurance by 10⁴ times than an MFM device without WS₂, a two-dimensional van der Waals-bonded transition metal chalcogenide.

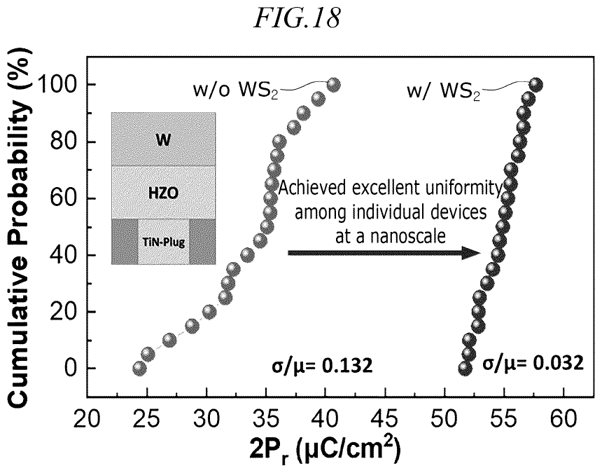

FIG. 18 is a graph showing comparison of ferroelectricity property variations at a nanoscale level depending on presence or absence of an interfacial layer of WS₂, a two-dimensional van der Waals-bonded transition metal chalcogenide. A conventional HZO has a critical limitation of significant differences among individual devices due to its random crystallinity upon manufacturing a nanoscale device. However, according to the present invention, the characteristic differences among devices at a nanoscale level (with a lower electrode diameter of 500 nm) are small as the crystallinity of HZO is improved and each domain structure is well aligned in a vertical direction by WS₂, a two-dimensional van der Waals-bonded transition metal chalcogenide.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Therefore, the technical scope of the present disclosure should be interpreted by the scope of the claims and equivalents thereof, instead of being restricted the disclosed description in Detailed Description.

What is claimed is:

1. A metal-ferroelectric-metal device comprising:
a first electrode;
an interfacial layer comprising a two-dimensional transition metal chalcogenide and formed on the first electrode;
a ferroelectric layer formed on the interfacial layer; and
a second electrode formed on the ferroelectric layer.

2. The metal-ferroelectric-metal device of claim 1,
wherein the interfacial layer is composed of a plurality of layers, and the plurality of layers are bonded via van der Waals interactions.

3. The metal-ferroelectric-metal device of claim 1,
wherein the interfacial layer functions as a seed layer for the ferroelectric layer to improve crystallinity or domain alignment of the ferroelectric layer.

4. The metal-ferroelectric-metal device of claim 1,
wherein the transition metal chalcogenide comprises one or more species of MoS₂, MoSe₂, MoTe₂, WS₂, WSe₂, WTe₂, ZrS₂, ZrSe₂, HfS₂, HfSe₂, NbSe₂, and ReSe₂.

5. The metal-ferroelectric-metal device of claim 1,
wherein a lattice constant of the transition metal chalcogenide in the interfacial layer is greater than or equal to 2.5 Å and less than or equal to 3.5 Å.

6. The metal-ferroelectric-metal device of claim 1,
wherein a thickness of the interfacial layer is greater than or equal to 0.5 nm and less than or equal to 5 nm

7. The metal-ferroelectric-metal device of claim 1,
wherein the ferroelectric layer comprises one or more species of hafnium oxide (HfO₂) and hafnium zirconium oxide (HfZrO)

8. The metal-ferroelectric-metal device of claim 1,
wherein the ferroelectric layer comprises a vertically aligned domain.

9. The metal-ferroelectric-metal device of claim 1,
wherein a ferroelectric material of the ferroelectric layer comprises o-phase among orthorhombic crystal structures, and a proportion of the o-phase is greater than or equal to 70%.

10. The metal-ferroelectric-metal device of claim 1,
wherein a variation in polarization of the metal-ferroelectric-metal device is less than 5% after 10⁴ or more cycles.

11. A method for manufacturing the metal-ferroelectric-metal device of claim 1, the method comprising:
i) forming a first electrode;
ii) forming an interfacial layer comprising a transition metal chalcogenide as a plurality of layers on the first electrode;
iii) forming a ferroelectric layer on the interfacial layer; and
iv) forming a second electrode on the ferroelectric layer.

12. The method for manufacturing a metal-ferroelectric-metal device of claim 11,
wherein in the step ii), the plurality of layers of the interfacial layer are bonded via van der Waals interactions.

13. The method for manufacturing a metal-ferroelectric-metal device of claim 11,
wherein in the step ii), the ferroelectric layer is formed by atomic layer deposition (ALD) or chemical vapor deposition (CVD).

14. The method for manufacturing a metal-ferroelectric-metal device of claim 13,
wherein in the step iii), the ferroelectric layer is formed by atomic layer deposition (ALD) or chemical vapor deposition (CVD) at a temperature greater than or equal to 200° C. and less than or equal to 250° C.

15. The method for manufacturing a metal-ferroelectric-metal device of claim 11, the method comprising crystallizing the ferroelectric layer under nitrogen atmosphere at a temperature greater than or equal to 300° C. and less than or equal to 650° C. after the step iv).
